(19) United States
(12) Patent Application Publication
(10) Pub. No.: US 2024/0120161 A1
(43) Pub. Date: Apr. 11, 2024

(54) KEYBOARD DEVICE

(71) Applicant: Primax Electronics Ltd., Taipei (TW)

(72) Inventors: Chin-Sung Pan, Taipei (TW); Bo-Hao Su, Taipei (TW); Chen-Hsuan Hsu, Taipei (TW)

(21) Appl. No.: 17/973,260

(22) Filed: Oct. 25, 2022

(30) Foreign Application Priority Data
Oct. 5, 2022 (TW) 111137871

(51) Int. Cl. H01H 13/702; H01H 13/02; H01H 13/14; H01H 13/20; H01H 13/83

(52) U.S. Cl. CPC H01H 13/702; H01H 13/023; H01H 13/14; H01H 13/20; H01H 13/83

(57) ABSTRACT

A keyboard device includes plural keycaps, a base plate, plural connecting elements and a circuit board. The plural connecting elements are connected with the respective keycaps and the base plate. The circuit board is located over the base plate. The circuit board includes plural membrane switches and plural first capacitance sensing units. When one of the first capacitance sensing units detects an approaching conductor or detects a motion of the conductor, a driving signal is generated or a control signal is outputted.

### FIELD OF THE INVENTION

The present invention relates to an input device, and more particularly to a keyboard device.

### BACKGROUND OF THE INVENTION

In modern societies, electronic devices become indispensable parts in human lives. The electronic products are applied in many sectors, including food, clothing, housing, transportation, education and entertainment. For facilitating carrying and using electronic products, the trends of designing electronic products are toward light weightiness and slimness.

Generally, an electronic product is equipped with a keyboard device. As the volume of the electronic product is gradually reduced, many of the original operating functions of the keyboard device are omitted. The keyboard device lack of the original operating functions cannot meet the diversified needs of electronic products in today's society.

In order to overcome the drawbacks of the conventional technologies, it is important to provide a keyboard device with additional operating functions while reducing the volume.

### SUMMARY OF THE INVENTION

The present invention provides a keyboard device with additional operating functions while reducing the volume.

In accordance with an aspect of the present invention, a keyboard device is provided. The keyboard device includes plural keycaps, a base plate, plural connecting elements, a circuit board and plural elastic elements. The plural connecting elements are connected with the respective keycaps and the base plate. Each of the plural keycap is movable upwardly or downwardly relative to the base plate through the corresponding connecting element. The circuit board is located over the base plate. The circuit board includes plural membrane switches and plural first capacitance sensing units. The circuit board includes a spacer layer, a first membrane circuit layer, a second membrane circuit layer and a protective layer. The first membrane circuit layer is located under the spacer layer. The second membrane circuit layer is located over the spacer layer. The protective layer is located over the second membrane circuit layer. The plural elastic elements are arranged between the respective keycaps and the circuit board, and aligned with the plural membrane switches, respectively. The plural membrane switches are arranged between the first membrane circuit layer and the second membrane circuit layer. The plural first capacitance sensing units are arranged between the protective layer and the second membrane circuit layer. When one of the plural first capacitance sensing units detects an approaching conductor or detects a motion of the conductor, a driving signal is generated or a control signal is outputted.

In an embodiment, the spacer layer includes plural perforations corresponding to the plural elastic elements, respectively. A first conductive contact of each membrane switch is formed on a top surface of the first membrane circuit layer and aligned with the corresponding perforation. A second conductive contact of the membrane switch is formed on a bottom surface of the second membrane circuit layer and aligned with the corresponding perforation.

In an embodiment, one of the plural keycaps is pressed in response to an external force, the corresponding elastic element is subjected to deformation, and the corresponding second conductive contact is moved downwardly and contacted with the corresponding first conductive contact. Consequently, a key signal is generated.

In an embodiment, each of the plural first capacitance sensing unit includes a first receiver electrode and a first transmitter electrode. The first receiver electrode is surrounded by the first transmitter electrode. The first receiver electrode and the first transmitter electrode are separated from each other.

In an embodiment, the circuit board further includes at least one second capacitance sensing unit. The at least one second capacitance sensing unit is arranged between the first membrane circuit layer and the spacer layer or arranged between the spacer layer and the second membrane circuit layer. The at least one second capacitance sensing unit detects an ambient information in an environment. The plural first capacitance sensing units are calibrated according to the detected ambient information.

In an embodiment, each of the at least one second capacitance sensing unit includes a second receiver electrode and a second transmitter electrode. The second receiver electrode is surrounded by the second transmitter electrode. The second receiver electrode and the second transmitter electrode are separated from each other.

In an embodiment, each of the plural connecting elements includes a first frame and a second frame.

In an embodiment, the keyboard device further includes plural light-emitting units corresponding to the plural keycaps. The plural light-emitting units are installed on the protective layer.

In an embodiment, when the conductor is detected by at least one first capacitance sensing unit of the plural first capacitance sensing units, the circuit board is driven according to the driving signal. When the circuit board is driven, at least one of the plural light-emitting units near the at least one first capacitance sensing unit projects a light beam to at least one of the plural keycaps.

In an embodiment, the circuit board includes plural pressable regions and a non-pressable regions. The non-pressable region is arranged between the plural pressable regions.

In an embodiment, the plural membrane switches are included in the corresponding pressable regions, and the plural first capacitance sensing units are included in the non-pressable region.

In an embodiment, a sensing distance of each of the plural first capacitance sensing units lies between 3 centimeters and 5 centimeters.

From the above descriptions, the present invention provides the keyboard device for an electronic device. In the keyboard device, the non-contact capacitance sensing unit is installed in the circuit board. Since the inner space of the keyboard device is effectively used, the volume of the electronic device is reduced. Furthermore, due to the arrangement of the capacitance sensing unit, the user can control the keyboard device according to the additional operating function, or the keyboard device can generate the corresponding control signal according to the motion of the hand gesture.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic top view illustrating a keyboard device according to the present invention;

FIG. 2A is a schematic perspective view illustrating a key structure of the keyboard device according to a first embodiment of the present invention;

FIG. 2B is a schematic exploded view illustrating the key structure according to the first embodiment of the present invention;

FIG. 3A is a schematic cross-sectional view illustrating the circuit board as shown in FIG. 2B and taken along the line A-A′;

FIG. 3B is a schematic top view illustrating the first capacitance sensing unit of the key structure according to the first embodiment of the present invention;

FIGS. 4A and 4B schematically illustrate two scenarios of using the keyboard device of the first embodiment to detect conductors;

FIG. 5 is a schematic top view illustrating a keyboard device according to a second embodiment of the present invention;

FIG. 6A is a schematic cross-sectional view illustrating the circuit board as shown in FIG. 5 and taken along the line A-A′;

FIG. 6B is a schematic top view illustrating a second capacitance sensing unit of the key structure according to the second embodiment of the present invention; and

FIG. 7 schematically illustrates an additional scenario of using the keyboard device of the second embodiment to detect an ambient information.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

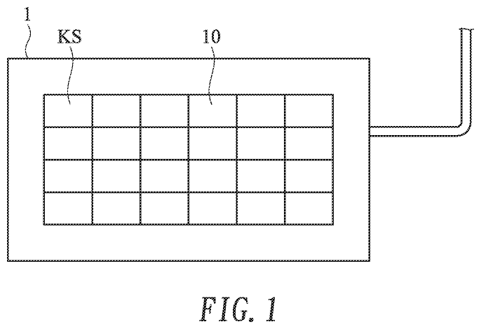

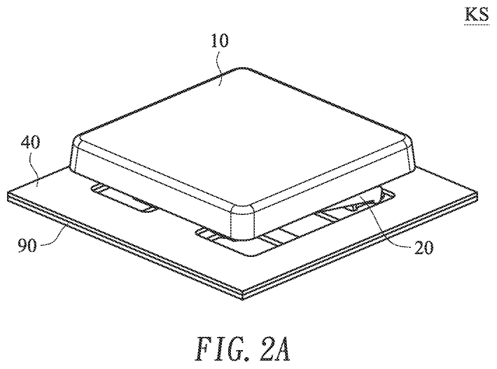

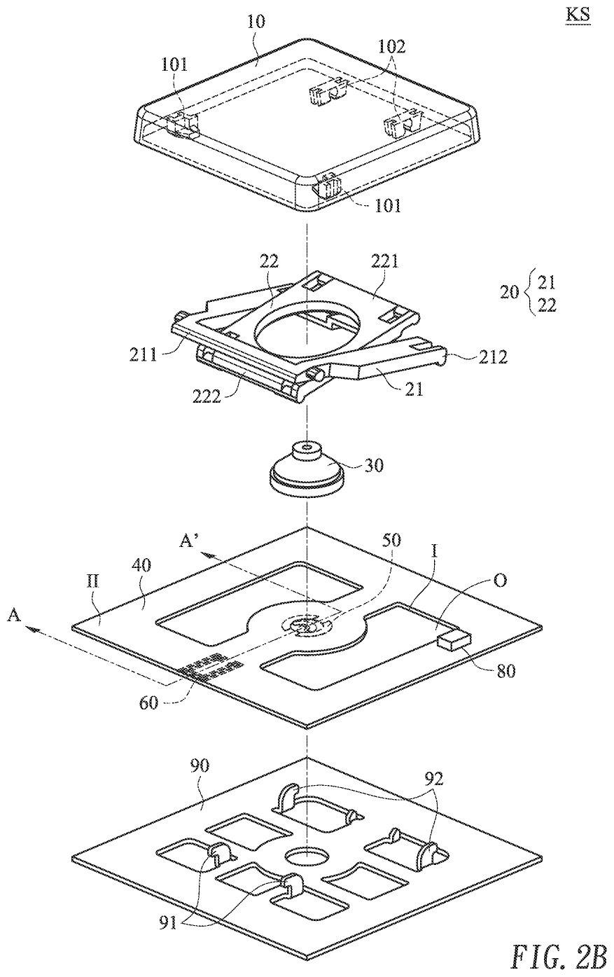

Please refer to FIGS. 1, 2A and 2B. FIG. 1 is a schematic top view illustrating a keyboard device according to the present invention. FIG. 2A is a schematic perspective view illustrating a key structure of the keyboard device according to a first embodiment of the present invention. FIG. 2B is a schematic exploded view illustrating the key structure according to the first embodiment of the present invention.

In this embodiment, the keyboard device 1 comprises plural key structures KS. Each key structure KS comprises a keycap 10, a connecting element 20, an elastic element 30, a circuit board 40, a membrane switch 50, a first capacitance sensing unit 60, a light-emitting unit 80 and a base plate 90. In an embodiment, the circuit board 40 and the base plate 90 are shared by the plural key structure KS. Under this circumstance, the plural key structures KS comprises plural keycaps 10, plural connecting elements 20, plural elastic elements 30, one circuit board 40, plural membrane switches 50, plural first capacitance sensing units 60, plural light-emitting units 80 and one base plate 90.

The membrane switch 50 and the first capacitance sensing unit 60 are installed in the circuit board 40. The light-emitting unit 80 is disposed on the circuit board 40. In addition, the light-emitting unit 80 corresponds to the keycap 10. The circuit board 40 is located over the base plate 90. The elastic element 30 is arranged between the keycap 10 and the circuit board 40. In addition, the elastic element 30 is aligned with the membrane switch 50. The base plate 20 is arranged around the elastic element 30. Moreover, the keycap 10 and the base plate 90 are connected with each other through the supporting element 20.

In this embodiment, the circuit board 40 comprises plural pressable regions I and a non-pressable regions II. The non-pressable region II is arranged between the plural pressable regions I. In this context, the pressable regions I are the regions of the circuit board 40 under the keycaps 10, and the other region of the circuit board 40 is the non-pressable regions II. The membrane switch 50 is included in the corresponding pressable region I. Moreover, two avoidance openings O are formed in the pressable region I. The first capacitance sensing unit 60 is included in the non-pressable region II. In an embodiment, the light-emitting unit 80 is included in the non-pressable region II. In addition, the light-emitting unit 80 is located at a junction between the pressable region I and the non-pressable region II. It is noted that the position of the light-emitting unit 80 is not restricted to the non-pressable region II. For example, in another embodiment, the light-emitting unit 80 is included in the pressable region I, and the light-emitting unit 80 is located at a position that is not sheltered by the connecting element 20.

In an embodiment, plural first coupling parts 101 and plural second coupling parts 102 are formed on a bottom surface of the keycap 10. The connecting element 20 comprises a first frame 21 and a second frame 22. The first frame 21 has a first end 211 and a second end 212, which are opposed to each other. The second frame 22 has a first end 221 and a second end 222, which are opposed to each other. The base plate 90 comprises plural third coupling parts 91 and plural fourth coupling parts 92. The third coupling parts 91 and the fourth coupling parts 92 are penetrated through or exposed to the corresponding avoidance openings O of the circuit board 40.

A process of assembling one of the plural key structures KS of the keyboard device 1 will be described as follows. Firstly, the first frame 21 and the second frame 22 of the connecting element 20 are pivotally coupled with each other through a pivot shaft (not shown). The first end 211 of the first frame 21 is coupled with the first coupling parts 101 of the keycap 10. The second end of the first frame 21 is coupled with the fourth coupling parts 92 of the base plate 90. The first end 221 of the second frame 22 is coupled with the second coupling parts 102 of the keycap 10. The second end 222 of the second frame 22 is coupled with the third coupling parts 91 of the base plate 90. Consequently, the first frame 21 and the second frame 22 are rotatably connected with the keycap 10 and the base plate 90. Moreover, through the cooperation of the first frame 21 and the second frame 22, the keycap 10 is movable upwardly or downwardly relative to the base plate 90.

In this embodiment, the connecting element 20 is a scissors-type connecting element. It is noted that the example of the connecting element 20 is not restricted. For example, in another embodiment, the connecting element 20 includes a V-shaped linkage rod, an A-shaped linkage rod or two parallel linkage rods.

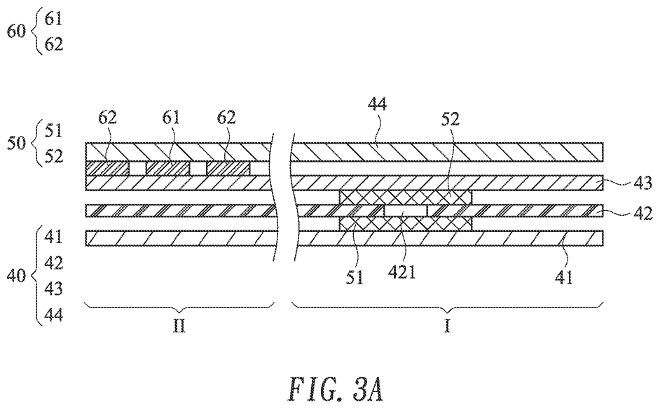

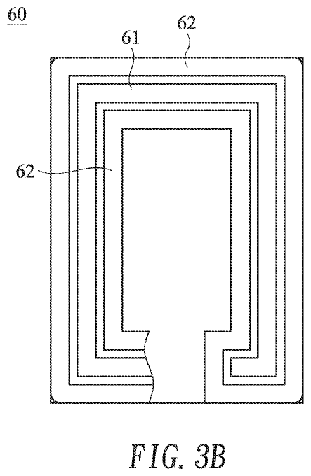

Please refer to FIGS. 3A and 3B. FIG. 3A is a schematic cross-sectional view illustrating the circuit board as shown in FIG. 2B and taken along the line A-A′. FIG. 3B is a schematic top view illustrating the first capacitance sensing unit of the key structure according to the first embodiment of the present invention. For succinctness, the circuit pattern and the connecting lines for connecting associated functional units are not shown in the cross-sectional view of the circuit board 40.

From top to bottom, the circuit board 40 comprises a first membrane circuit layer 41, a spacer layer 42, a second membrane circuit layer 43 and a protective layer 44 sequentially. The membrane switch 50 is arranged between the first membrane circuit layer 41 and the second membrane circuit layer 43. In this embodiment, the spacer layer 42 comprises a perforation 421. The installation position of the perforation 421 is aligned with the elastic element 30 (see FIG. 2B). A first conductive contact 51 of the membrane switch 50 is formed on a top surface of the first membrane circuit layer 41 and aligned with the perforation 421. A second conductive contact 52 of the membrane switch 50 is formed on a bottom surface of the second membrane circuit layer 43 and aligned with the perforation 421.

When the keycap 10 as shown in FIG. 2B is pressed down in response to an external force, the corresponding elastic element 30 is subjected to deformation so as to push the first membrane circuit layer 41. As the first membrane circuit layer 41 is pushed by the elastic element 30, the corresponding second conductive contact 52 is moved downwardly, penetrated through the perforation 421 and contacted with the corresponding first conductive contact 51. Consequently, a key signal is generated.

The first capacitance sensing unit 60 is arranged between the protective layer 44 and the second membrane circuit layer 43. The first capacitance sensing unit 60 is used to detect a conductor approaching the keyboard device 1 or detect the motion of the conductor. When the conductor or the motion of the conductor is detected, the keyboard device 1 generates a driving signal or outputs a control signal. For example, the conductor is the user's finger or the user' palm.

In an embodiment, the first capacitance sensing unit 60 comprises a first receiver electrode 61 (i.e., an RX electrode) and a first transmitter electrode 62 (i.e., a TX electrode). The first receiver electrode 61 is surrounded by the first transmitter electrode 62. Moreover, the first receiver electrode 61 and the first transmitter electrode 62 are separated from each other. Consequently, a projected capacitive structure is formed between the first transmitter electrode 62 and the first receiver electrode 61 in order to detect the approaching state or the motion state of the conductor.

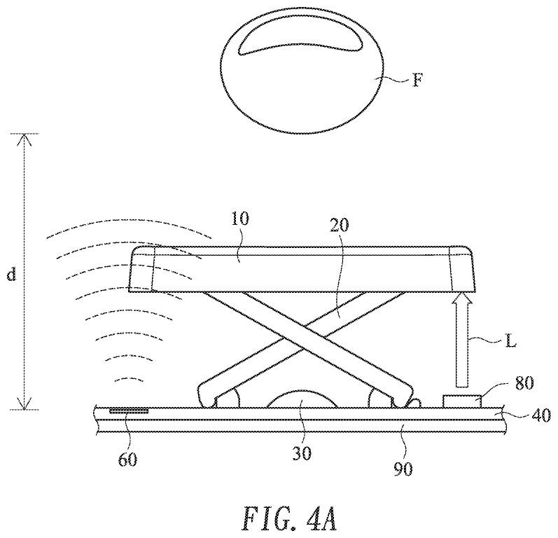

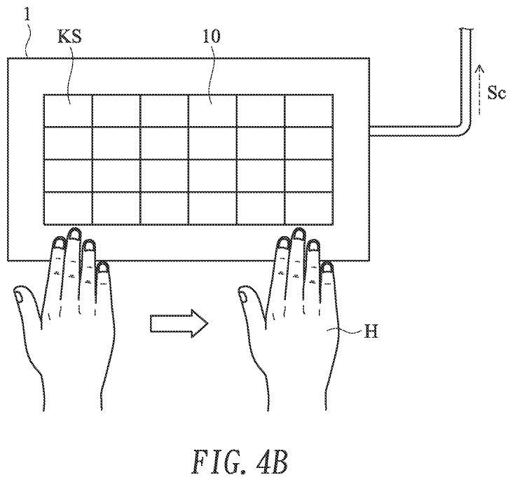

Please refer to FIGS. 4A and 4B. FIGS. 4A and 4B schematically illustrate two scenarios of using the keyboard device of the first embodiment to detect conductors.

In the scenario of FIG. 4A, a finger F approaches the keycap 10. When the first capacitance sensing unit 60 detects the conductor (i.e., the finger F), the keyboard device 1 generates a driving signal (not shown) to drive the circuit board 40. According to the driving signal, the light-emitting unit 80 near the first capacitance sensing unit 60 projects a light beam L to the keycap 10. Consequently, the keycap 10 is illuminated and recognized by the user. It is noted that numerous modifications and alterations may be made while retaining the teachings of the invention. In some embodiments, the light-emitting unit 80 projects the light beam L to plural neighboring keycaps 10, and thus the plural keycaps 10 near the first capacitance sensing unit 60 are illuminated simultaneously. In some other embodiments, plural light-emitting units 80 near the first capacitance sensing unit 60 are driven according to the driving signal from the keyboard device 1, and the plural light-emitting units 80 are driven to project the light beams L to the corresponding keycaps 10. Consequently, the plural keycaps 10 near the first capacitance sensing unit 60 are illuminated simultaneously. In an embodiment, the sensing distance d of the first capacitance sensing unit 60 for sensing the conductor (i.e., the finger F) lies between 3 centimeters and 5 centimeters.

In the scenario of FIG. 4B, a hand H lies within the range of the detecting distance d and moves over the keyboard device 1. When the first capacitance sensing unit 60 detects the motion of the hand H, the keyboard device 1 generates a control signal Sc corresponding to the gesture of the hand H. In an embodiment, when the hand F is moved in the left direction or the right direction, the keyboard device 1 generates the control signal Sc that is related to a page switching action. According to the control signal Sc, a web page shown on a display screen (not shown) is switched to the previous page or the next page. In another scenario, the keyboard device 1 is in a hibernation or a power-off state. When the first capacitance sensing unit 60 detects the hand H lies within the detecting distance d, the keyboard device 1 is waken up accordingly.

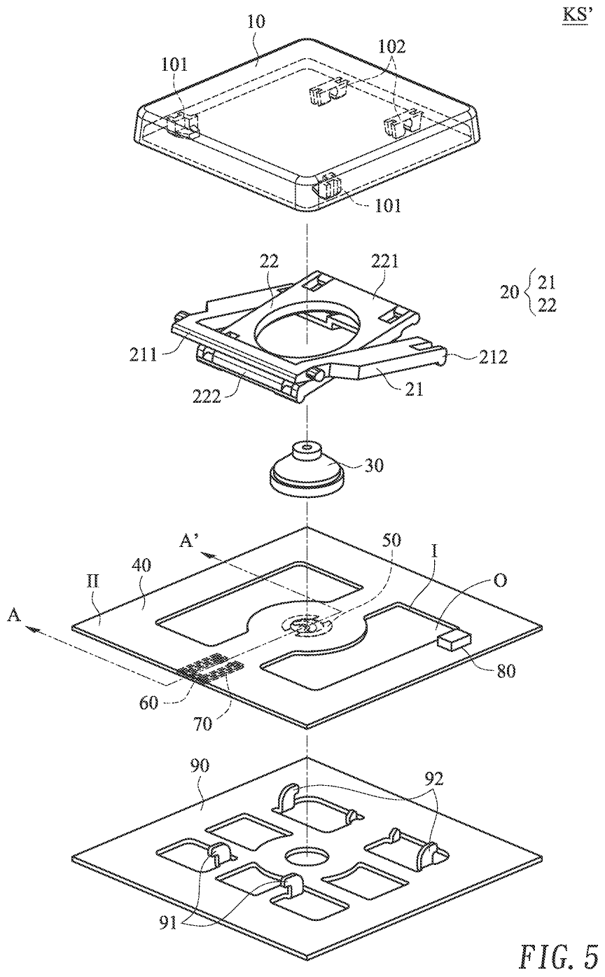

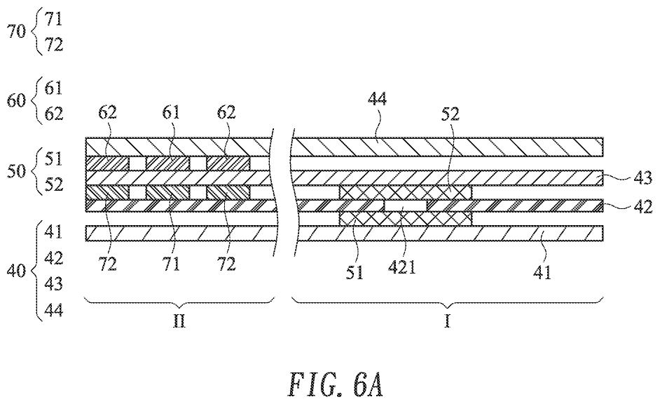

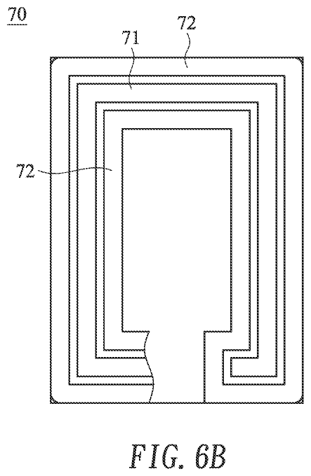

Please refer to FIGS. 5, 6A and 6B. FIG. 5 is a schematic top view illustrating a keyboard device according to a second embodiment of the present invention. FIG. 6A is a schematic cross-sectional view illustrating the circuit board as shown in FIG. 5 and taken along the line A-A′. FIG. 6B is a schematic top view illustrating a second capacitance sensing unit of the key structure according to the second embodiment of the present invention. The components and functions of the key structure KS' that are similar to those of the key structure KS of the first embodiment are not redundantly described herein. In comparison with the first embodiment, the key structure KS' of the second embodiment further comprises at least one second capacitance sensing unit 70. In this embodiment, the second capacitance sensing unit 70 is arranged between the spacer layer 42 and the second membrane circuit layer 43. The second capacitance sensing unit 70 comprises a second receiver electrode 71 (i.e., an RX electrode) and a second transmitter electrode 72 (i.e., a TX electrode). The second receiver electrode 71 is surrounded by the second transmitter electrode 72. Moreover, the second receiver electrode 71 and the second transmitter electrode 72 are separated from each other. Consequently, a projected capacitive structure is formed between the second transmitter electrode 72 and the second receiver electrode 71 in order to detect the environmental state. In some other possible embodiments, the second capacitance sensing unit 70 is arranged between the first membrane circuit layer 41 and the spacer layer 42.

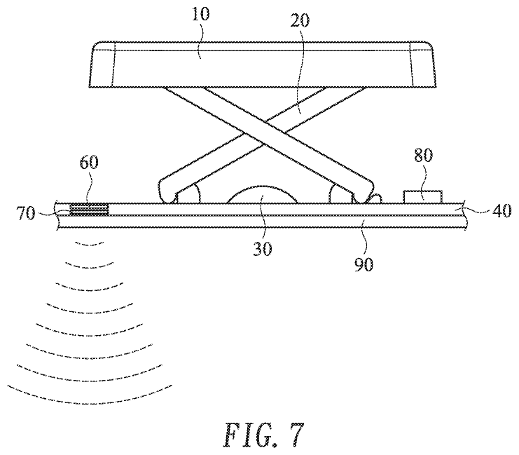

FIG. 7 schematically illustrates an additional scenario of using the keyboard device of the second embodiment to detect an ambient information. The second capacitance sensing unit 70 is used to detect the ambient information in the environment of the keyboard device 1. For example, when the keyboard device 1 is placed on a table surface (not shown), the second capacitance sensing unit 70 can detect the ambient information in the environment of the table surface. That is, the second capacitance sensing unit 70 can be used to detect whether there is a conductive object, an interference source or any other possible ambient information in the environment. According to the detected ambient information, an integrated circuit (not shown) of the circuit board 40 adjusts the power for the operation of the first capacitance sensing unit 60. After the power for the operation of the first capacitance sensing unit 60 is adjusted, the first capacitance sensing unit 60 is calibrated. Consequently, the detecting distance d of the first capacitance sensing unit 60 can be maintained.

From the above descriptions, the present invention provides the keyboard device for an electronic device. In the keyboard device, the non-contact capacitance sensing unit is installed in the circuit board. Since the inner space of the keyboard device is effectively used, the volume of the electronic device is reduced. Furthermore, due to the arrangement of the capacitance sensing unit, the user can control the keyboard device according to the additional operating function, or the keyboard device can generate the corresponding control signal according to the motion of the hand gesture. In other words, the technologies of the present invention are industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A keyboard device, comprising:
plural keycaps;
a base plate;
plural connecting elements connected with the respective keycaps and the base plate, wherein each of the plural keycap is movable upwardly or downwardly relative to the base plate through the corresponding connecting element;
a circuit board located over the base plate, and comprising plural membrane switches and plural first capacitance sensing units, wherein the circuit board comprises a spacer layer, a first membrane circuit layer, a second membrane circuit layer and a protective layer, wherein the first membrane circuit layer is located under the spacer layer, the second membrane circuit layer is located over the spacer layer, and the protective layer is located over the second membrane circuit layer; and
plural elastic elements arranged between the respective keycaps and the circuit board, and aligned with the plural membrane switches, respectively,
wherein the plural membrane switches are arranged between the first membrane circuit layer and the second membrane circuit layer, and the plural first capacitance sensing units are arranged between the protective layer and the second membrane circuit layer,
wherein when one of the plural first capacitance sensing units detects an approaching conductor or detects a motion of the conductor, a driving signal is generated or a control signal is outputted.

2. The keyboard device according to claim 1, wherein the spacer layer comprises plural perforations corresponding to the plural elastic elements, respectively, wherein a first conductive contact of each membrane switch is formed on a top surface of the first membrane circuit layer and aligned with the corresponding perforation, and a second conductive contact of the membrane switch is formed on a bottom surface of the second membrane circuit layer and aligned with the corresponding perforation.

3. The keyboard device according to claim 2, wherein when one of the plural keycaps is pressed in response to an external force, the corresponding elastic element is subjected to deformation, and the corresponding second conductive contact is moved downwardly and contacted with the corresponding first conductive contact, so that a key signal is generated.

4. The keyboard device according to claim 1, wherein each of the plural first capacitance sensing unit comprises a first receiver electrode and a first transmitter electrode, wherein the first receiver electrode is surrounded by the first transmitter electrode, and the first receiver electrode and the first transmitter electrode are separated from each other.

5. The keyboard device according to claim 1, wherein the circuit board further comprises at least one second capacitance sensing unit, wherein the at least one second capacitance sensing unit is arranged between the first membrane circuit layer and the spacer layer or arranged between the spacer layer and the second membrane circuit layer, wherein the at least one second capacitance sensing unit detects an ambient information in an environment, and the plural first capacitance sensing units are calibrated according to the detected ambient information.

6. The keyboard device according to claim 5, wherein each of the at least one second capacitance sensing unit comprises a second receiver electrode and a second transmitter electrode, wherein the second receiver electrode is surrounded by the second transmitter electrode, and the second receiver electrode and the second transmitter electrode are separated from each other.

7. The keyboard device according to claim 1, wherein each of the plural connecting elements comprises a first frame and a second frame.

8. The keyboard device according to claim 1, wherein the keyboard device further comprises plural light-emitting units corresponding to the plural keycaps, wherein the plural light-emitting units are installed on the protective layer.

9. The keyboard device according to claim 8, wherein when the conductor is detected by at least one first capacitance sensing unit of the plural first capacitance sensing units, the circuit board is driven according to the driving signal, wherein when the circuit board is driven, at least one of the plural light-emitting units near the at least one first capacitance sensing unit projects a light beam to at least one of the plural keycaps.

10. The keyboard device according to claim 1, wherein the circuit board comprises plural pressable regions and a non-pressable regions, wherein the non-pressable region is arranged between the plural pressable regions.

11. The keyboard device according to claim 10, wherein the plural membrane switches are included in the corresponding pressable regions, and the plural first capacitance sensing units are included in the non-pressable region.

12. The keyboard device according to claim 1, wherein a sensing distance of each of the plural first capacitance sensing units lies between 3 centimeters and 5 centimeters.
